(19) United States
(12) Patent Application Publication
(10) Pub. No.: US 2024/0177976 A1
(43) Pub. Date: May 30, 2024

(54) LINER STRUCTURE AND SUBSTRATE PROCESSING APPARATUS INCLUDING THE SAME

(71) Applicant: SEMES CO., LTD., Chungcheongnam-do (KR)

(72) Inventors: Hyoungkyu SON, Seoul-si (KR); Juyong JANG, Seongnam-si (KR)

(21) Appl. No.: 18/514,080

(22) Filed: Nov. 20, 2023

(30) Foreign Application Priority Data
Nov. 28, 2022 (KR) 10-2022-0162048

(51) Int. Cl. H01J 37/32

(52) U.S. Cl. CPC H01J 37/32522; H01J 37/32715; H01J 2237/2001; H01J 2237/2007

(57) ABSTRACT

Provided is a liner structure including a liner body, a heating coil arranged in the liner body and configured to heat the liner body, and a magnetic coil arranged below the heating coil in the liner body and configured to generate a magnetic field.

### CROSS-REFERENCE TO RELATED APPLICATION

This application is based on and claims priority under 35 U.S.C. § 119 to Korean Patent Application No. 10-2022-0162048, filed on Nov. 28, 2022, in the Korean Intellectual Property Office, the disclosure of which is incorporated by reference herein in its entirety.

### BACKGROUND

### 1. Field

The disclosure relates to a liner structure and a substrate processing apparatus including the same, and more particularly, to a liner structure including a coil and a substrate processing apparatus including the liner structure.

### 2. Description of the Related Art

In a process for manufacturing a semiconductor device, plasma is used in various processes, such as etching, deposition, cleaning, and the like. In a process using plasma, the density and shape of the plasma needs to be appropriately controlled to improve the quality of a semiconductor device. During plasma processing, a liner structure is arranged on an inner wall of a chamber to protect the inner wall of the chamber from the plasma. At this time, particles or the like generated during plasma processing may be deposited on the liner structure. Such particles or the like may affect subsequent plasma processing, thereby deteriorating the quality of a semiconductor device manufactured using the plasma processing. Accordingly, there is a need for a liner structure capable of appropriately controlling the density and shape of plasma while preventing particle deposition.

### SUMMARY

Provided are a liner structure capable of appropriately controlling the density and shape of plasma used in plasma processing, while preventing particles generated by the plasma processing from being deposited on a surface, and a substrate processing apparatus including the liner structure.

Additional aspects will be set forth in part in the description which follows and, in part, will be apparent from the description, or may be learned by practice of the presented embodiments of the disclosure.

According to an aspect of the disclosure, a liner structure includes a liner body, a heating coil arranged in the liner body and configured to heat the liner body, and a magnetic coil arranged below the heating coil in the liner body and configured to generate a magnetic field.

In an embodiment, the magnetic coil may be wound multiple times in a vertical direction.

In an embodiment, the magnetic coil may include a conductive coil layer having an opening therein, and an insulating coil layer covering the conductive coil layer.

In an embodiment, the conductive coil layer may include copper (Cu), and the insulating coil layer may include ceramic.

In an embodiment, the heating coil may be wound one time.

In an embodiment, a diameter of the magnetic coil may be less than a diameter of the heating coil.

According to another aspect of the disclosure, a substrate processing apparatus includes a chamber including an upper chamber and a lower chamber and configured to provide a processing space in which plasma processing is performed, a liner structure arranged on the lower chamber and configured to protect an inner wall of the lower chamber, and a substrate support arranged in the processing space and including a support chuck and a support rod, the support chuck being configured to support a substrate on which the plasma processing is performed, and the support rod being connected to the support chuck, wherein the liner structure includes a liner body including a horizontal portion and a vertical portion, the horizontal portion being arranged on an upper surface of the lower chamber, and the vertical portion protruding from the horizontal portion toward the inner wall of the lower chamber and extending in a vertical direction perpendicular to the upper surface of the lower chamber, a heating coil arranged in the horizontal portion and configured to heat the liner body, and a magnetic coil arranged in the vertical portion and configured to generate a magnetic field.

In an embodiment, the substrate processing apparatus may further include a first power device configured to supply direct current power to the magnetic coil, and a second power device configured to supply direct current power to the heating coil.

In an embodiment, the substrate processing apparatus may further include a first power line connecting the first power device to the magnetic coil, and a second power line connecting the second power device to the heating coil, wherein a diameter of the first power line may be less than a diameter of the second power line.

In an embodiment, the substrate processing apparatus may further include a control device configured to control an operation of the first power device and an operation of the second power device.

In an embodiment, the control device may be further configured to control the first power device to supply relatively high first power to the magnetic coil while the plasma processing is performed, and control the first power device to supply relatively low power to the magnetic coil while the plasma processing is not performed.

In an embodiment, the substrate processing apparatus may further include an insulating structure arranged on an outer wall of the horizontal portion of the liner body.

In an embodiment, the substrate processing apparatus may further include a shielding structure covering an outer wall of the lower chamber.

In an embodiment, the vertical portion may be spaced apart from the inner wall of the lower chamber in a horizontal direction parallel to the upper surface of the lower chamber.

In an embodiment, the magnetic coil may be wound multiple times in the vertical direction such that a lowermost end of the magnetic coil may be located between an upper surface of the support chuck and a lower surface of the support chuck.

In an embodiment, the magnetic coil may include a conductive coil layer having an opening therein, and an insulating coil layer covering the conductive coil layer.

In an embodiment, the heating coil may be wound one time.

In an embodiment, a diameter of the magnetic coil may be less than a diameter of the heating coil.

In an embodiment, the substrate processing apparatus may further include an upper electrode arranged on the substrate support to face the support chuck of the substrate support.

According to another aspect of the disclosure, a substrate processing apparatus includes a chamber including an upper chamber and a lower chamber and configured to provide a processing space in which plasma processing is performed, a liner structure arranged on the lower chamber and configured to protect an inner wall of the lower chamber, a substrate support arranged in the processing space and including a support chuck and a support rod, the support chuck being configured to support a substrate on which the plasma processing is performed, and the support rod being connected to the support chuck, an upper electrode arranged on the substrate support to face the support chuck, a first power device configured to supply power to a magnetic coil of the liner structure, a second power device configured to supply power to a heating coil of the liner structure, a shielding structure covering an outer wall of the lower chamber, and an insulating structure arranged on an outer wall of the liner structure, wherein the liner structure includes a liner body including a horizontal portion and a vertical portion, the horizontal portion being arranged on an upper surface of the lower chamber, and the vertical portion protruding from the horizontal portion toward the inner wall of the lower chamber, extending in a vertical direction perpendicular to the upper surface of the lower chamber, and spaced apart from the inner wall of the lower chamber, the heating coil wound one time in the horizontal portion and configured to heat the liner body, and the magnetic coil wound multiple times in the vertical direction in the vertical portion and configured to generate a magnetic field.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a substrate processing apparatus according to an embodiment;

FIG. 2 is an enlarged cross-sectional view of region EX of FIG. 1;

FIG. 3 is a cross-sectional view taken along line A-A′ of FIG. 1;

FIGS. 4A and 4B are cross-sectional views illustrating an operation of a substrate processing apparatus according to an embodiment; and

FIGS. 5A and 5B are cross-sectional views illustrating an operation of a substrate processing apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the disclosure will be described in detail with reference to the accompanying drawings. The same elements in the drawings are denoted by the same reference numerals, and redundant descriptions thereof are omitted.

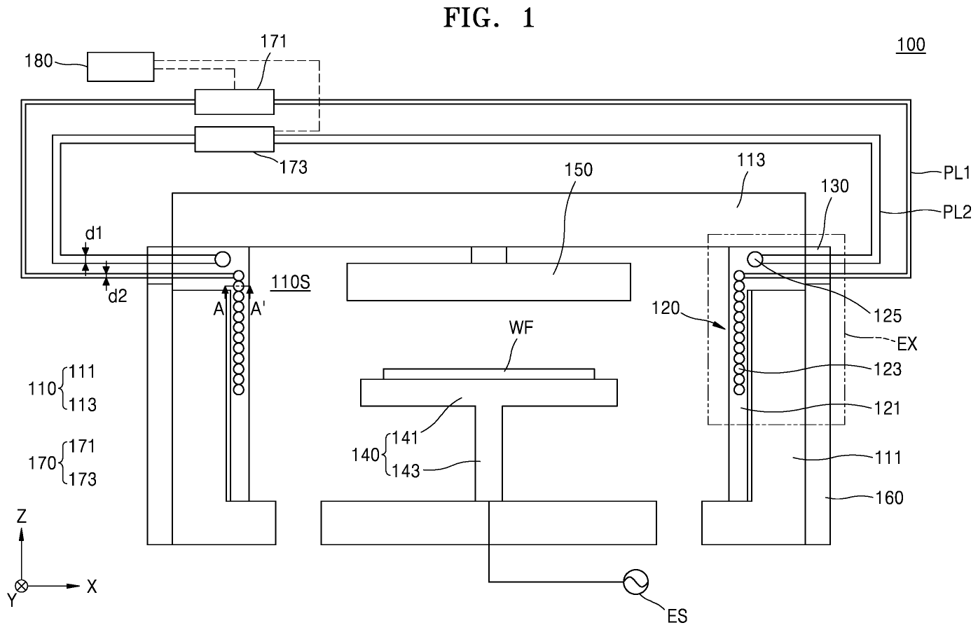

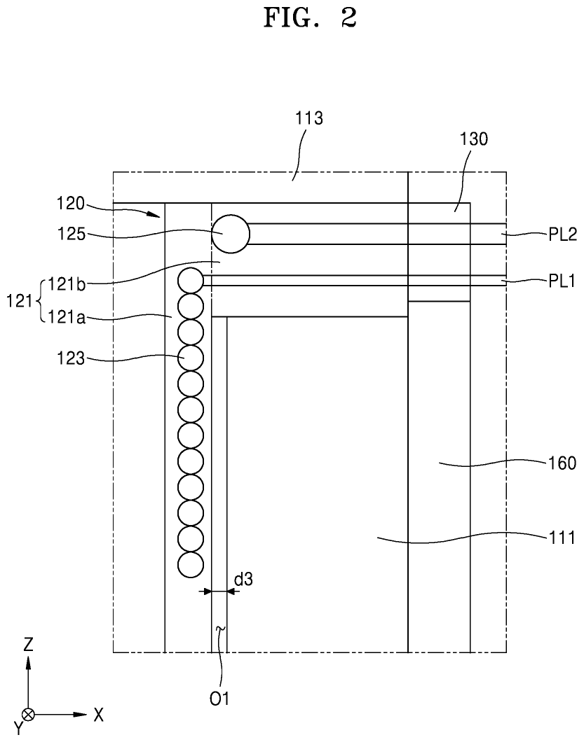

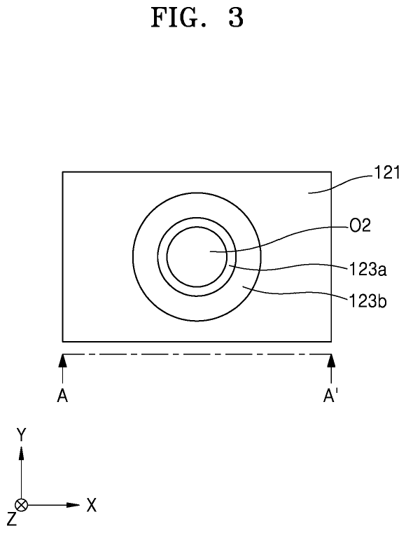

FIG. 1 is a cross-sectional view illustrating a substrate processing apparatus 100 according to an embodiment. FIG. 2 is an enlarged cross-sectional view of region EX of FIG. 1. FIG. 3 is a cross-sectional view taken along line A-A′ of FIG. 1.

Referring to FIGS. 1 and 2, the substrate processing apparatus 100 may include a chamber 110, a liner structure 120, a substrate support 140, and an upper electrode 150.

The chamber 110 may provide a processing space 110S in which plasma processing is performed on a substrate WF. The substrate WF may be, for example, a silicon substrate. In an embodiment, the chamber 110 may have a cylindrical shape, but embodiments are not limited thereto.

The chamber 110 may include a lower chamber 111 and an upper chamber 113. The lower chamber 111, the upper chamber 113, and the liner structure 120 may provide together the processing space 110S in which plasma processing is performed on the substrate WF. The lower chamber 111 and the upper chamber 113 may include the same material. For example, the lower chamber 111 and the upper chamber 113 may each include aluminum. An exhaust port (not illustrated) may be provided on a lower surface of the lower chamber 111. A process gas or the like in the processing space 110S may be exhausted from the processing space 110S to the outside through the exhaust port. At least one of the upper chamber 113 and the lower chamber 111 may be moved in a vertical direction (a Z direction). For example, the upper chamber 113 may be moved upward in the vertical direction (the Z direction) to be away from the lower chamber 111 when the substrate WF is carried into the processing space 110S or taken out of the processing space 110S, and may be moved downward in the vertical direction (the Z direction) to be close to the lower chamber 111 when plasma processing is performed on the substrate WF. However, embodiments are not limited thereto, and the lower chamber 111 may be moved upward and downward in the vertical direction (the Z direction), or both the upper chamber 113 and the lower chamber 111 may be moved upward and downward in the vertical direction (the Z direction).

The liner structure 120 may be arranged between the lower chamber 111 and the upper chamber 113. While plasma processing is performed on the substrate WF, the liner structure 120 may prevent an inner wall of the lower chamber 111 from being damaged by plasma. The liner structure 120 may include a liner body 121, a magnetic coil 123, and a heating coil 125.

The liner body 121 may prevent the inner wall of the lower chamber 111 from being damaged by plasma. The liner body 121 may be include, for example, an insulating material such as quartz. The liner body 121 may have a rotated L shape as a whole. The liner body 121 may include a vertical portion 121a and a horizontal portion 121b.

The horizontal portion 121b may be arranged on an upper surface of the lower chamber 111. The horizontal portion 121b may extend inward (i.e., toward the processing space 110S) beyond the lower chamber 111 in a horizontal direction (an X direction) parallel to the upper surface of the lower chamber 111. At this time, the horizontal portion 121b may extend inward beyond the lower chamber 111 by a first length d3.

The vertical portion 121a may protrude inward (i.e., toward the processing space 110S) from the horizontal portion 121b in the horizontal direction (the X direction). In an embodiment, the vertical portion 121a may extend in the vertical direction (the Z direction) perpendicular to the horizontal direction. Accordingly, the vertical portion 121a may be located between the processing space 110S and the inner wall of the lower chamber 111 to protect the inner wall of the lower chamber 111 from plasma. In an embodiment, the vertical portion 121a may be spaced apart from the inner wall of the lower chamber 111 in the horizontal direction (the X direction). Accordingly, an empty space O1 of which the length in the horizontal direction (the length in the X direction) is the first length d3 may be provided between the vertical portion 121a and the inner wall of the lower chamber 111. Because the inner wall of the lower chamber 111 and the vertical portion 121a are spaced apart from each other, even when the lower chamber 111 and the liner structure 120 expand by receiving heat generated while plasma processing is performed, damage to the lower chamber 111 and the liner structure 120 due to collision between the lower chamber 111 and the liner structure 120 caused by the thermal expansion may be prevented.

In FIG. 2, the vertical portion 121a and the horizontal portion 121b are separately described. However, this is for convenience of description, and the vertical portion 121a and the horizontal portion 121b may be integrally formed as a single body. In an embodiment, an upper surface of the vertical portion 121a and an upper surface of the horizontal portion 121b may be located at the same vertical level.

The magnetic coil 123 may be arranged in the liner body 121. In detail, the magnetic coil 123 may be arranged in the vertical portion 121a of the liner body 121. In an embodiment, the magnetic coil 123 may be wound multiple times in the vertical direction (the Z direction) in the vertical portion 121a. In this case, a lowermost end of the magnetic coil 123 that is wound multiple times in the vertical direction may be located between an upper surface of a support chuck 141 and a lower surface of the support chuck 141 in the vertical direction, and an uppermost end of the magnetic coil 123 that is wound multiple times in the vertical direction may be located between the upper surface of the lower chamber 111 and the heating coil 125 in the vertical direction.

Referring to FIG. 3, in an embodiment, the magnetic coil 123 may include a conductive coil layer 123a and an insulating coil layer 123b covering the conductive coil layer 123a. The conductive coil layer 123a may have an opening O2 therein. However, embodiments are not limited thereto, and the conductive coil layer 123a may have a cylindrical core (not illustrated) filling the inside thereof. The conductive coil layer 123a may include a conductor capable of generating a magnetic field by receiving power. For example, the conductive coil layer 123a may include a conductor such as copper. The insulating coil layer 123b may cover the conductive coil layer 123a. By covering the conductive coil layer 123a, the insulating coil layer 123b may separate the conductive coil layer 123a from the liner body 121. For example, the insulating coil layer 123b may include ceramic such as magnesium oxide (MgO).

The magnetic coil 123 may generate a magnetic field and heat by receiving power. Accordingly, the density and shape of plasma generated in the processing space 110S may be controlled through the magnetic field generated by the magnetic coil 123, and the heat generated by the magnetic coil 123 may be transferred to a lower portion of the vertical portion 121a of the liner body 121, and thus, deposition of particles or the like generated by plasma processing or the like on the lower portion of the vertical portion 121a of the liner body 121 may be prevented.

Referring back to FIGS. 1 and 2, the heating coil 125 may be arranged in the liner body 121. In detail, the heating coil 125 may be arranged in the horizontal portion 121b of the liner body 121. In an embodiment, the heating coil 125 may be a coil that is wound one time in the horizontal portion 121b. In this case, the heating coil 125 may have a donut shape. In an embodiment, the diameter of the magnetic coil 123 may be less than the diameter of the heating coil 125. Accordingly, power supplied to the magnetic coil 123 may be relatively less than power supplied to the heating coil 125.

An insulating structure 130 may be arranged on an outer wall of the horizontal portion 121b of the liner body 121. The insulating structure 130 may be configured to be attached to or detached from the outer wall of the horizontal portion 121b. The insulating structure 130 may surround a portion of a first power line PL1 extending from the liner body 121 to the outside and a portion of a second power line PL2 extending from the liner body 121 to the outside. As a result, the insulating structure 130 may physically and electrically separate the first power line PL1 and the second power line PL2 from each other. In an embodiment, the insulating structure 130 may include ceramic or the like.

The substrate support 140 may be arranged in the processing space 110S. In detail, the substrate support 140 may be arranged on the lower surface of the lower chamber 111 in the processing space 110S. In an embodiment, the substrate support 140 may be arranged in a central portion of the processing space 110S. The substrate support 140 may be configured to support the substrate WF. In an embodiment, the substrate support 140 may function as a lower electrode for generating plasma in the processing space 110S. The substrate support 140 may include the support chuck 141 and a support rod 143.

The support chuck 141 may be configured to support the substrate WF. In an embodiment, the support chuck 141 may be an electrostatic chuck. In an embodiment, the support chuck 141 may function as a lower electrode for generating plasma by receiving power from a power generator ES.

The support rod 143 may be connected to the support chuck 141. The support rod 143 may support the support chuck 141. The support rod 143 may include a power line (not illustrated) for providing power received from the power generator ES to the support chuck 141.

The power generator ES may apply power to the substrate support 140. In detail, the power generator ES may supply power to the support chuck 141 through the support rod 143. The power supplied by the power generator ES may be, for example, radio-frequency (RF) power, but embodiments are not limited thereto.

The upper electrode 150 may be arranged on a lower surface of the upper chamber 113 in the processing space 110S. In an embodiment, the upper electrode 150 may be arranged to face the substrate support 140. The upper electrode 150 may function as an electrode for generating plasma in the processing space 110S. The upper electrode 150 may function as, for example, a ground electrode.

The upper electrode 150 may include a shower head (not illustrated). The shower head may include a plurality of holes (not illustrated). When a process gas is supplied to the shower head through a gas supply device (not illustrated), the process gas supplied to the shower head may be supplied into the processing space 110S through the plurality of holes of the shower head.

A shielding structure 160 covering an outer wall of the lower chamber 111 may be arranged on the outer wall of the lower chamber 111. In an embodiment, a lower surface of the shielding structure 160 may be located at the same vertical level as the lower surface of the lower chamber 111, and an upper surface of the shielding structure 160 may be located at a higher vertical level than the upper surface of the lower chamber 111. Accordingly, the shielding structure 160 may cover the entire outer wall of the lower chamber 111. In an embodiment, the shielding structure 160 may have a shape that is the same as or similar to that of the lower chamber 111. For example, when the lower chamber 111 has a cylindrical shape, the shielding structure 160 may have a cylindrical shape covering the outer wall of the lower chamber 111. Among magnetic fields generated by the magnetic coil 123 when power is supplied to the magnetic coil 123, the shielding structure 160 may shield a magnetic field generated on the outer wall of the chamber 110.

A power device 170 may comprise a first power device 171 and a second power device 173.

The first power device 171 may be configured to apply power to the magnetic coil 123. An operation of the first power device 171 may be controlled by a control device 180. In an embodiment, the first power device 171 may be configured to apply direct current power to the magnetic coil 123.

The second power device 173 may be configured to apply power to the heating coil 125. An operation of the second power device 173 may be controlled by the control device 180. In an embodiment, the second power device 173 may be configured to apply direct current power to the heating coil 125.

The first power line PL1 may connect the magnetic coil 123 to the first power device 171. The first power device 171 may apply power to the magnetic coil 123 through the first power line PL1.

The second power line PL2 may connect the heating coil 125 to the second power device 173. The second power device 173 may apply power to the heating coil 125 through the second power line PL2.

In an embodiment, a diameter d2 of the first power line PL1 may be less than a diameter d1 of the second power line PL2. This is because, as described above, the diameter of the magnetic coil 123 is less than the diameter of the heating coil 125, and thus, the power applied to the magnetic coil 123 is less than the power applied to the heating coil 125.

The control device 180 may be configured to control an operation of the first power device 171 and an operation of the second power device 173. The control device 180 may be implemented in hardware, firmware, software, or any combination thereof. For example, the control device 180 may be a computing device, such as a workstation computer, a desktop computer, a laptop computer, a tablet computer, or the like. For example, the control device 180 may include a memory device, such as read only memory (ROM), random access memory (RAM), or the like, and a processor configured to execute certain operations and algorithms, for example, a microprocessor, a central processing unit (CPU), a graphics processing unit (GPU), or the like. In addition, the control device 180 may include a receiver and a transmitter for receiving and transmitting electrical signals.

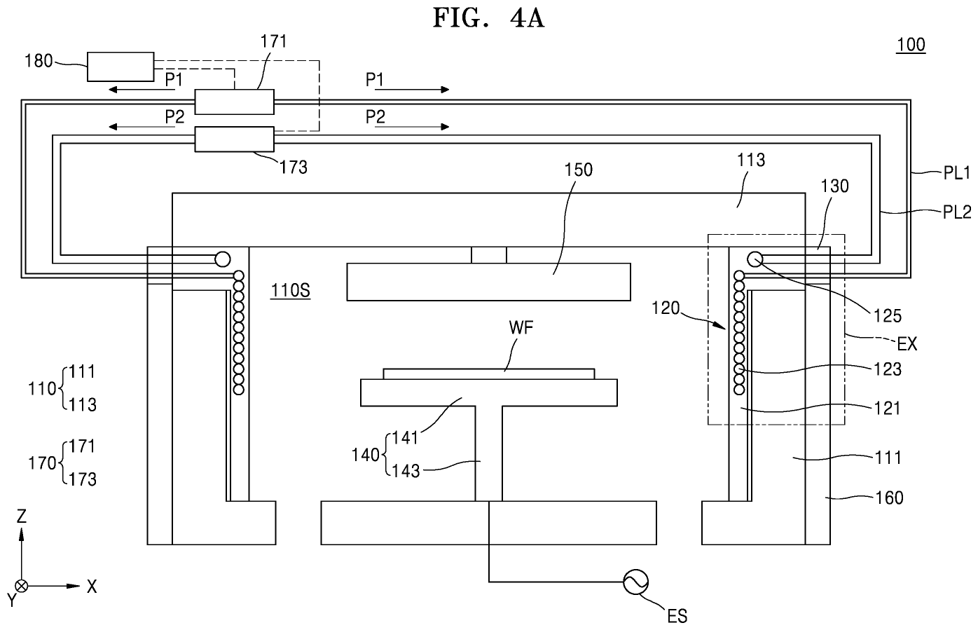

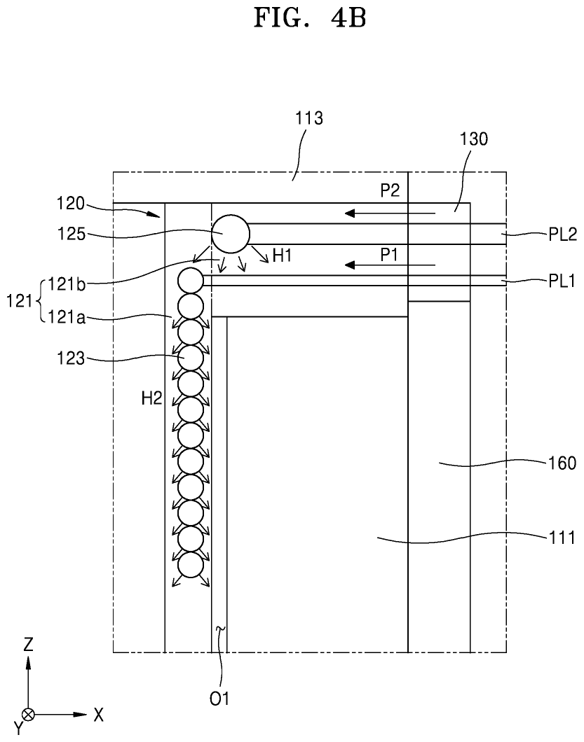

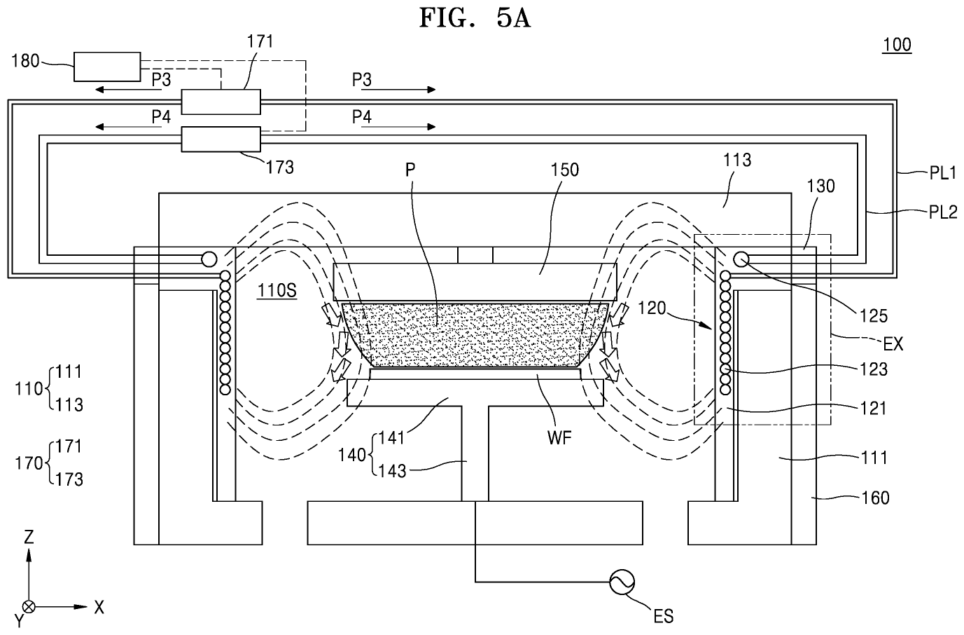

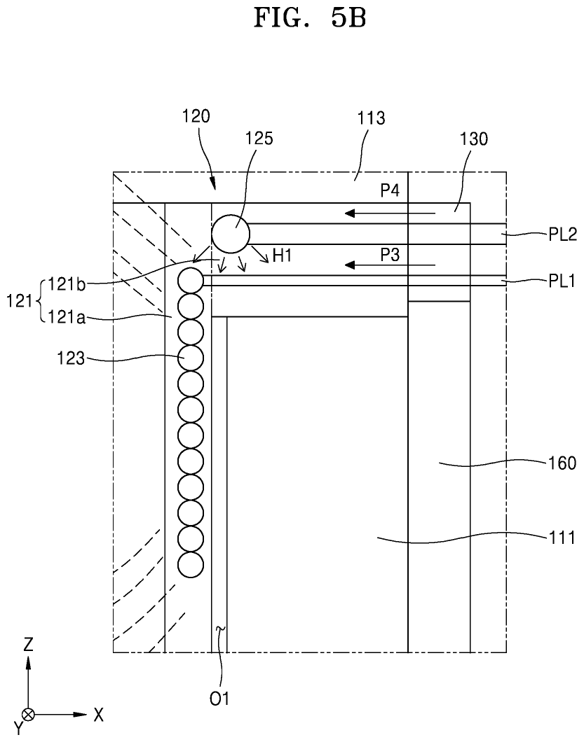

In an embodiment, the control device 180 may control the first power device 171 to supply relatively high power to the magnetic coil 123 while plasma processing is performed on the substrate WF, and may control the first power device 171 to supply relatively low power to the magnetic coil 123 while plasma processing is not performed on the substrate WF. Hereinafter, this aspect will be described in more detail with reference to FIGS. 4A, 4B, 5A, and 5B.

FIGS. 4A, 4B, 5A, and 5B are cross-sectional views illustrating an operation of the substrate processing apparatus 100 according to an embodiment. In detail, FIGS. 4A and 4B illustrate a case in which the first power device 171 supplies relatively low power to the magnetic coil 123, and FIGS. 5A and 5B illustrate a case in which the first power device 171 supplies relatively high power to the magnetic coil 123. In FIG. 4B, arrows indicate directions in which heat H2 generated by the magnetic coil 123 and heat H1 generated by the heating coil 125 are transferred. In addition, in FIG. 5A, arrows indicate directions in which plasma is concentrated by a magnetic field, and in FIGS. 5A and 5B, dotted lines indicate magnetic force lines of a magnetic field generated by the magnetic coil 123.

Referring to FIGS. 4A and 4B, the control device 180 may control the first power device 171 such that the first power device 171 supplies first power P1 to the magnetic coil 123, and may control the second power device 173 such that the second power device 173 supplies second power P2 to the heating coil 125. At this time, plasma processing may not be performed on the substrate WF.

Heat and a magnetic field may be generated by the magnetic coil 123 when the first power P1 is supplied thereto, and heat and a magnetic field may be generated by the heating coil 125 when the second power P2 is supplied thereto. However, because the first power P1 is relatively lower than third power P3 to be described below with reference to FIGS. 5A and 5B, the magnetic field generated by the magnetic coil 123 may not have a relatively large effect. In contrast, because the magnetic coil 123 is located below the heating coil 125, the heat H1 generated by the heating coil 125 may not be transferred to the lower portion of the vertical portion 121a of the liner body 121, but the heat H2 generated by the magnetic coil 123 may be transferred to the lower portion of the vertical portion 121a of the liner body 121. Accordingly, the heat H2 generated by the magnetic coil 123 and the heat H1 generated by the heating coil 125 may be transferred to the entire portion of the liner body 121, and thus, particles or the like generated while plasma processing is performed may not be deposited on the entire portion of the liner body 121.

Referring to FIGS. 5A and 5B, the control device 180 may control the first power device 171 such that the first power device 171 supplies third power P3 to the magnetic coil 123, and may control the second power device 173 such that the second power device 173 supplies fourth power P4 to the heating coil 125. In this case, plasma processing may be performed on the substrate WF.

Heat and a magnetic field may be generated by the magnetic coil 123 when the third power P3 is supplied thereto, and heat and a magnetic field may be generated by the heating coil 125 when the fourth power P4 is supplied thereto. In this case, because the third power P3 is relatively higher than the first power P1 described above with reference to FIGS. 4A and 4B, the magnetic field generated by the magnetic coil 123 may have a relatively large effect. Accordingly, the density and shape of plasma P in the processing space 110S may be controlled by the magnetic field generated by the magnetic coil 123. For example, by intensifying the magnetic field generated by the magnetic coil 123, the plasma P in the processing space 110S may be more concentrated toward the central portion of the processing space 110S, and by weakening the magnetic field generated by the magnetic coil 123, the plasma P in the processing space 110S may spread to edges of the processing space 110S.

In an embodiment, the fourth power P4 may have the same intensity as that of the first power P1. Accordingly, the heat generated by the heating coil 125 by supplying the fourth power P4 thereto may be the heat H1.

A liner structure of the related art includes a heating coil, but does not separately include a magnetic coil arranged below the liner structure. Accordingly, there may be limitations in controlling the density and shape of plasma generated in a chamber through a magnetic field generated by supplying power to the heating coil. In addition, due to limitations in heat transfer, heat generated by the heating coil may not be transferred to a lower portion of the liner structure. Accordingly, the temperature of the lower portion of the liner structure may be relatively lower than the temperature of an upper portion of the liner structure, and thus, foreign substances, such as particles or the like, generated by plasma processing may be deposited on the lower portion of the liner structure. The presence of these particles may affect subsequent plasma processing, and thus, the quality of a semiconductor device manufactured using the plasma processing may deteriorate.

In contrast, the liner structure according to an embodiment includes a heating coil in a horizontal portion of a liner body, and includes a magnetic coil in a vertical portion of the liner body. The density and shape of plasma generated in a chamber may be appropriately controlled through a magnetic field generated by supplying power to the heating coil and the magnetic coil. In addition, heat generated by the heating coil may be transferred to the horizontal portion of the liner body, and heat generated by the magnetic coil may be transferred to the vertical portion of the liner body. Accordingly, heat may be transferred to the entire region of the liner structure including the liner body, and thus, foreign substances, such as particles or the like, generated by plasma processing may not be deposited on the entire region of the liner structure. As a result, subsequent plasma processing may be performed better, and thus, the quality of a semiconductor device manufactured using the plasma processing may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A liner structure comprising:
a liner body;
a heating coil arranged in the liner body and configured to heat the liner body; and
a magnetic coil arranged below the heating coil in the liner body and configured to generate a magnetic field.

2. The liner structure of claim 1, wherein the magnetic coil is wound multiple times in a vertical direction.

3. The liner structure of claim 1, wherein the magnetic coil comprises:
a conductive coil layer having an opening therein; and
an insulating coil layer covering the conductive coil layer.

4. The liner structure of claim 3, wherein the conductive coil layer comprises copper (Cu), and
the insulating coil layer comprises ceramic.

5. The liner structure of claim 1, wherein the heating coil is wound one time.

6. The liner structure of claim 1, wherein a diameter of the magnetic coil is less than a diameter of the heating coil.

7. A substrate processing apparatus comprising:
a chamber comprising an upper chamber and a lower chamber and configured to provide a processing space in which plasma processing is performed;
a liner structure arranged on the lower chamber and configured to protect an inner wall of the lower chamber; and
a substrate support arranged in the processing space and comprising a support chuck and a support rod, the support chuck being configured to support a substrate on which the plasma processing is performed, and the support rod being connected to the support chuck,
wherein the liner structure comprises:
a liner body comprising a horizontal portion and a vertical portion, the horizontal portion being arranged on an upper surface of the lower chamber, and the vertical portion protruding from the horizontal portion toward the inner wall of the lower chamber and extending in a vertical direction perpendicular to the upper surface of the lower chamber;
a heating coil arranged in the horizontal portion and configured to heat the liner body; and
a magnetic coil arranged in the vertical portion and configured to generate a magnetic field.

8. The substrate processing apparatus of claim 7, further comprising:
a first power device configured to supply direct current power to the magnetic coil; and
a second power device configured to supply direct current power to the heating coil.

9. The substrate processing apparatus of claim 8, further comprising:
a first power line connecting the first power device to the magnetic coil; and
a second power line connecting the second power device to the heating coil,
wherein a diameter of the first power line is less than a diameter of the second power line.

10. The substrate processing apparatus of claim 8, further comprising a control device configured to control an operation of the first power device and an operation of the second power device.

11. The substrate processing apparatus of claim 10, wherein the control device is further configured to:
control the first power device to supply relatively high first power to the magnetic coil while the plasma processing is performed; and
control the first power device to supply relatively low power to the magnetic coil while the plasma processing is not performed.

12. The substrate processing apparatus of claim 7, further comprising an insulating structure arranged on an outer wall of the horizontal portion of the liner body.

13. The substrate processing apparatus of claim 7, further comprising a shielding structure covering an outer wall of the lower chamber.

14. The substrate processing apparatus of claim 7, wherein the vertical portion is spaced apart from the inner wall of the lower chamber in a horizontal direction parallel to the upper surface of the lower chamber.

15. The substrate processing apparatus of claim 7, wherein the magnetic coil is wound multiple times in the vertical direction such that a lowermost end of the magnetic coil is located between an upper surface of the support chuck and a lower surface of the support chuck.

16. The substrate processing apparatus of claim 7, wherein the magnetic coil comprises:
a conductive coil layer having an opening therein; and
an insulating coil layer covering the conductive coil layer.

17. The substrate processing apparatus of claim 7, wherein the heating coil is wound one time.

18. The substrate processing apparatus of claim 7, wherein a diameter of the magnetic coil is less than a diameter of the heating coil.

19. The substrate processing apparatus of claim 7, further comprising an upper electrode arranged on the substrate support to face the support chuck of the substrate support.

20. A substrate processing apparatus comprising:
a chamber comprising an upper chamber and a lower chamber and configured to provide a processing space in which plasma processing is performed;
a liner structure arranged on the lower chamber and configured to protect an inner wall of the lower chamber;
a substrate support arranged in the processing space and comprising a support chuck and a support rod, the support chuck being configured to support a substrate on which the plasma processing is performed, and the support rod being connected to the support chuck;
an upper electrode arranged on the substrate support to face the support chuck;
a first power device configured to supply power to a magnetic coil of the liner structure;
a second power device configured to supply power to a heating coil of the liner structure;
a shielding structure covering an outer wall of the lower chamber; and
an insulating structure arranged on an outer wall of the liner structure,
wherein the liner structure comprises:
a liner body comprising a horizontal portion and a vertical portion, the horizontal portion being arranged on an upper surface of the lower chamber, and the vertical portion protruding from the horizontal portion toward the inner wall of the lower chamber, extending in a vertical direction perpendicular to the upper surface of the lower chamber, and spaced apart from the inner wall of the lower chamber;
the heating coil wound one time in the horizontal portion and configured to heat the liner body; and
the magnetic coil wound multiple times in the vertical direction in the vertical portion and configured to generate a magnetic field.
